(19) United States
(12) Patent Application Publication
(10) Pub. No.: US 2026/0246490 A1
(43) Pub. Date: Aug. 20, 2026

(54) REPLICA SIGNAL GENERATOR FOR SIMULTANEOUS BIDIRECTIONAL DATA COMMUNICATION LINK

(71) Applicant: QUALCOMM Incorporated, San Diego, CA (US)

(72) Inventors: Jeffrey Mark HINRICHS, San Diego, CA (US); Ashwin SETHURAM, San Clemente, CA (US)

(21) Appl. No.: 19/054,353

(22) Filed: Feb. 14, 2025

(51) Int. Cl. H04B 1/40; G06F 13/20; H03H 17/00; H03H 17/02

(52) U.S. Cl. CPC H04B 1/40; G06F 13/20; H03H 17/02; G06F 2213/40; H03H 2017/0081

(57) ABSTRACT

An apparatus, comprising: a first input/output (I/O) circuit comprising: a first transmit driver; a first continuous-time (CT) finite impulse response (FIR) replica signal generator including an input directly or indirectly coupled to an input of the first transmit driver; a first signal combiner including a first input coupled to an output of the first transmit driver, and a second input coupled to an output of the first CT FIR replica signal generator; and a first receiver including a first input coupled to an output of the first signal combiner.

### FIELD

This disclosure relates generally to data communication links, and in particular, to a replica signal generator for a simultaneous bidirectional data communication link.

### BACKGROUND

A pair of integrated circuits (ICs) may be coupled together via a data communication link. The data communication link may be serializer/deserializer (SERDES) data communication link including a dedicated unidirectional data lane for transmitting data from the first IC to the second IC, and a second dedicated unidirectional data lane for transmitting data from the second IC to the first IC. The data communication link may also be a simultaneous bidirectional data communication link that allows the first and second ICs to simultaneously transmit data to each other via a bidirectional communication channel. Such bidirectional communication channels present some challenges with separating the transmit signal from the receive signal at each end of the communication link.

### SUMMARY

The following presents a simplified summary of one or more implementations in order to provide a basic understanding of such implementations. This summary is not an extensive overview of all contemplated implementations, and is intended to neither identify key or critical elements of all implementations nor delineate the scope of any or all implementations. Its sole purpose is to present some concepts of one or more implementations in a simplified form as a prelude to the more detailed description that is presented later.

An aspect of the disclosure relates to an apparatus. The apparatus includes: a first input/output (I/O) circuit comprising: a first transmit driver; a first continuous-time (CT) finite impulse response (FIR) replica signal generator including an input directly or indirectly coupled to an input of the first transmit driver; a first signal combiner including a first input coupled to an output of the first transmit driver, and a second input coupled to an output of the first CT FIR replica signal generator; and a first receiver including a first input coupled to an output of the first signal combiner.

Another aspect of the disclosure relates to a method. The method includes: providing a first transmit signal to a first end of a communication channel, wherein the first transmit signal includes a set of one or more signal reflection artifacts; receiving a first receive signal at the first end of the communication channel, the first receiving signal being sent from a second end of the communication channel; generating a first replica transmit signal including a set of one or more replica signal reflection artifacts; combining the first transmit signal, the first receive signal, and the first replica transmit signal such that the first replica transmit signal and the first transmit signal substantially cancels out, while outputting substantially the first receive signal; and detecting data in the outputted first receive signal.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the description implementations are intended to include all such aspects and their equivalents.

### BRIEF DESCRIPTION OF THE DRAWINGS

FIG. 1 illustrates a block diagram of an example serializer/deserializer (SERDES) communication link in accordance with an aspect of the disclosure.

FIG. 2A illustrates a block diagram of an example simultaneous bidirectional data communication link in accordance with another aspect of the disclosure.

FIG. 2B illustrates graphs of example data signals associated with the simultaneous bidirectional data communication link of FIG. 2A in accordance with another aspect of the disclosure.

FIG. 2C illustrates a block/signal diagram of a portion of the example simultaneous bidirectional data communication link of FIG. 2A in accordance with another aspect of the disclosure.

FIG. 3 illustrates a block diagram of an example simultaneous bidirectional data communication link in accordance with another aspect of the disclosure.

FIG. 4 illustrates a block diagram of an example continuous-time (CT) finite impulse response (FIR) replica signal generator in accordance with another aspect of the disclosure.

FIG. 5 illustrates a schematic diagram of an example equivalent circuit of the continuous-time (CT) finite impulse response (FIR) replica signal generator of FIG. 4 in accordance with another aspect of the disclosure.

FIG. 6 illustrates a block diagram of another example continuous-time (CT) finite impulse response (FIR) replica signal generator in accordance with another aspect of the disclosure.

FIG. 7 illustrates graphs of example data signals generated by the continuous-time (CT) finite impulse response (FIR) replica signal generator of FIG. 4 in accordance with another aspect of the disclosure.

FIG. 8 illustrates a flow diagram of an example method of receiving a data signal in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts. The term “substantially” means that the associated parameter may not be exact as indicated but accounts for some variation due to specified tolerances.

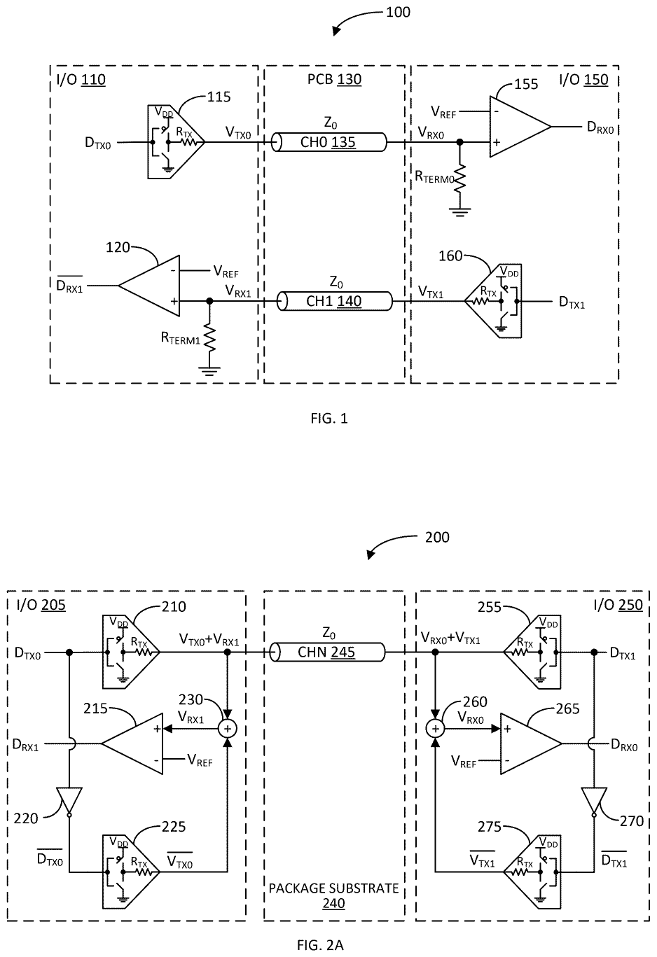

FIG. 1 illustrates a block diagram of an example serializer/deserializer (SERDES) communication link 100 in accordance with an aspect of the disclosure. The SERDES communication link 100 may be used to transmit data between two integrated circuits (ICs) via communication channels, which may be implemented on a printed circuit board (PCB).

In particular, the SERDES communication link 100 includes a first input/output (I/O) circuit 110 (e.g., which may be implemented in a first IC) including a channel zero (CH0) transmit driver 115, a channel one (CH1) receiver 120, and a CH1 termination resistor R_{TERM1}. The SERDES communication link 100 further includes a second I/O circuit 150 (e.g., which may be implemented in a second IC) including a CH0 receiver (e.g., VGA and/or CTLE) 155, a CH0 termination resistor R_{TERM0}, and a CH1 transmit driver 160. Additionally, the SERDES communication link 100 includes a PCB 130 includes a CH0 communication channel 135 (e.g., one or more PCB metallization traces (e.g., single-ended, differential, or pseudo-differential)), and a CH1 communication channel 140 (e.g., one or more PCB metallization traces (e.g., single-ended, differential, or pseudo-differential)).

The CH0 transmit driver 115 is configured to receive and power amplify a CH0 transmit data signal D_{TX0} to generate a CH0 transmit signal V_{TX0}. The CH0 transmit driver 115 may include an output impedance or resistance of R_{TX} (e.g., 35 Ohms (Ω)). The output of the CH0 transmit driver 115 may be coupled to a first (e.g., left) end of the CH0 communication channel 135. The CH0 communication channel 135 may have a characteristic impedance of Z₀ (e.g., 50Ω). The CH0 transmit signal V_{TX0} propagates through the CH0 communication channel 135 to a second (e.g., right) end thereof. The CH0 communication channel 135 affects the CH0 transmit signal V_{TX0} (e.g., produces high frequency losses in the CH0 transmit signal V_{TX0}) to produce a CH0 receive signal V_{RX0} at the second I/O circuit 150.

The CH0 receiver 155 includes a first (e.g., negative) input configured to receive a reference voltage V_{REF} (e.g., at a common mode voltage level). The CH0 receiver 155 includes a second (e.g., positive) input configured to receive the CH0 receive signal V_{RX0}. The CH0 termination resistor R_{TERM0} (e.g., at substantially Z₀ or 50Ω) coupled between the second (e.g., positive) input of the CH0 receiver 155 and a lower voltage rail (e.g., ground). The CH0 termination resistor R_{TERM0} is configured to reduce signal reflections at the second (e.g., positive) input of the CH0 receiver 155. The CH0 receiver 155 is configured to compare the CH0 receive signal V_{RX0} with the reference voltage V_{REF} to generate a CH0 receive data signal D_{RX0}. It shall be understood that some data signals are depicted as being non-inverted (e.g., D_{RX0}). However, it shall be understood that data signals, whether indicated as non-inverted or inverted, refer to the same data signals.

Similarly, the CH1 transmit driver 160 is configured to receive and power amplify a CH1 transmit data signal D_{TX1} to generate a CH1 transmit signal V_{TX1}. The CH1 transmit driver 160 may also include an output impedance or resistance of R_{TX} (e.g., 35Ω). The output of the CH1 transmit driver 160 may be coupled to a first (e.g., right) end of the CH1 communication channel 140. The CH1 communication channel 140 may have a characteristic impedance of Z₀ (e.g., 50Ω). The CH1 transmit signal V_{TX1} propagates through the CH1 communication channel 140 to a second (e.g., left) end thereof. The CH1 communication channel 140 affects the CH1 transmit signal V_{TX1} (e.g., produces high frequency losses in the CH1 transmit signal V_{TX1}) to produce a CH1 receive signal V_{RX1} at the first I/O circuit 110.

The CH1 receiver (e.g., a variable gain amplifier (VGA) and/or a continuous time linear equalizer (CTLE)) 120 includes a first (e.g., negative) input configured to receive a reference voltage V_{REF} (e.g., at a common mode voltage level). The CH1 receiver 120 includes a second (e.g., positive) input configured to receive the CH1 receive signal V_{RX1}. The CH1 termination resistor R_{TERM1} (e.g., at substantially Z₀ or 50Ω) is coupled between the second (e.g., positive) input of the CH1 receiver 120 and the lower voltage rail (e.g., ground). The CH1 termination resistor R_{TERM1} is configured to reduce signal reflections at the second (e.g., positive) input of the CH1 receiver 120. The CH1 receiver 120 is configured to compare the CH1 receive signal V_{RX1} with the reference voltage V_{REF} to generate a CH1 receive data signal D_{RX1}.

The SERDES communication link 100 may be appropriate for transmitting data between monolithic processor ICs. However, for smaller ICs, such as chiplets, the SERDES communication link 100 may be too large, in terms of package substrate footprint, to for chiplets. Instead, as discussed further herein, a simultaneous bidirectional data communication link may be more appropriate for data transmission between chiplets.

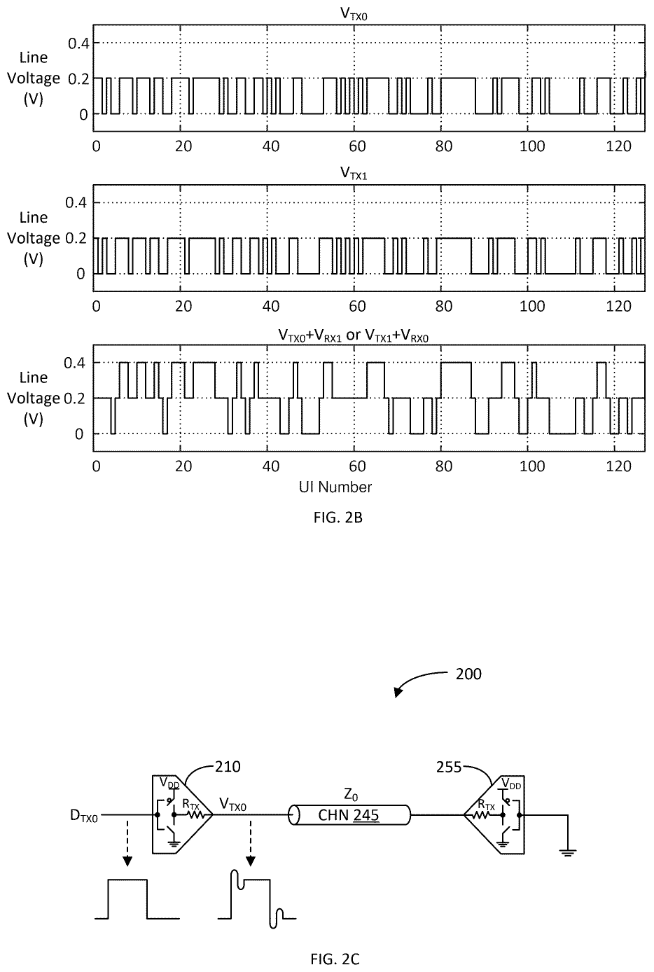

FIG. 2A illustrates a block diagram of an example simultaneous bidirectional data communication link 200 in accordance with another aspect of the disclosure. The simultaneous bidirectional data communication link 200 may be used to data couple two ICs (e.g., chiplets) via a communication channel implemented on a package substrate.

In particular, the simultaneous bidirectional data communication link 200 includes a first I/O circuit 205 (e.g., which may be implemented in a first IC or chiplet) including a channel zero (CH0) transmit driver 210, a channel one (CH1) receiver (e.g., VGA and/or CTLE) 215, a signal combiner (e.g., a summer) 230, an inverter 220, and a CH0 replica transmit driver 225. The simultaneous bidirectional data communication link 200 further includes a second I/O circuit 250 (e.g., which may be implemented in a second IC or chiplet) including a CH1 transmit driver 255, a CH0 receiver (e.g., VGA and/or CTLE) 265, a signal combiner (e.g., a summer) 260, an inverter 270, and a CH1 replica transmit driver 275. Further, the simultaneous bidirectional data communication link 200 further includes a package substrate 240 having a bidirectional communication channel 245 (e.g., one or more PCB metallization traces (e.g., single-ended, differential, or pseudo-differential)).

The CH0 transmit driver 210 is configured to receive and power amplify a CH0 transmit data signal D_{TX0} to generate a CH0 transmit signal V_{TX0}. The CH0 transmit driver 210 may include an output impedance or resistance of R_{TX} (e.g., 35Ω). The output of the CH0 transmit driver 210 may be coupled to a first (e.g., left) end of the communication channel 245. The communication channel 245 may have a characteristic impedance of Z₀ (e.g., 50Ω). The CH0 transmit signal V_{TX0} propagates through the communication channel 245 to a second (e.g., right) end thereof. The communication channel 245 affects the CH0 transmit signal V_{TX0} (e.g., produces high frequency losses in the CH0 transmit signal V_{TX0}) to produce a CH0 receive signal V_{RX0} at the second I/O circuit 250.

The CH1 transmit driver 255 is configured to receive and power amplify a CH1 transmit data signal D_{TX1} to generate a CH1 transmit signal V_{TX1}. The CH1 transmit driver 255 may include an output impedance or resistance of R_{TX} (e.g., 35Ω). The output of the CH1 transmit driver 255 may be coupled to the second (e.g., right) end of the communication channel 245. The CH1 transmit signal V_{TX1} propagates through the communication channel 245 to the first (e.g., left) end thereof. The communication channel 245 affects the CH1 transmit signal V_{TX1} (e.g., produces high frequency losses in the CH1 transmit signal V_{TX1}) to produce a CH1 receive signal V_{RX1} at the first I/O circuit 205.

The first and second transmit signals V_{TX0} and V_{TX1} may be transmitted simultaneously. Accordingly, at the output of the CH0 transmit driver 210, the CH0 transmit signal V_{TX0} combines or sums with the CH1 receive signal V_{RX1}. To process the CH1 receive signal V_{RX1} to generate a CH1 receive data signal D_{RX1}, the CH0 transmit signal V_{TX0} should be substantially removed from a first (e.g., positive) input of the CH1 receiver 215. In this regard, the output of the CH0 transmit driver 210 is coupled to a first input of the signal combiner 230.

The inverter 220 includes an input coupled to the input of the CH0 transmit driver 210 to receive the CH0 transmit data signal D_{TX0}. The inverter 220 is configured to invert the CH0 transmit data signal D_{TX0} to generate an inverted CH0 transmit data signal D̅_̅{̅T̅X̅0̅}̅. The CH0 replica transmit driver 225 includes an input coupled to the output of the inverter 220 to receive the inverted CH0 transmit data signal D̅_̅{̅T̅X̅0̅}̅. The replica transmit driver 225 is configured to power amplify the inverted CH0 transmit data signal D̅_̅{̅T̅X̅0̅}̅ to generate a replica CH0 transmit signal V̅_̅{̅T̅X̅0̅}̅. The replica transmit driver 225 includes an output coupled to a second input of the signal combiner 230.

The CH1 receiver 215 includes a first (e.g., positive) input coupled to an output of the signal combiner 230. Due to the inverter 220 and the replica transmit driver 225, the replica CH0 transmit signal V̅_̅{̅T̅X̅0̅}̅ is substantially equal in amplitude and opposite in phase (e.g., 180 degree out-of-phase) to the CH0 transmit signal V_{TX0}. Thus, the replica CH0 transmit signal V̅_̅{̅T̅X̅0̅}̅ substantially cancels out the CH0 transmit signal V_{TX0} at the output of the signal combiner 230. Accordingly, the signal combiner 230 is configured to substantially output only the CH1 receive signal V_{RX1}. The CH1 receiver 215 includes a second (e.g., negative) input configured to receive a reference voltage V_{REF} (e.g., at a common mode voltage level). Accordingly, the first (e.g., positive) input of the CH1 receiver 215 is configured to receive the CH1 receive signal V_{RX1}. The CH1 receiver 215 is configured to compare the CH1 receive signal V_{RX1} with the reference voltage V_{REF} to generate the CH1 receive signal D_{RX1}.

Similarly, as previously discussed, the first and second transmit signals V_{TX0} and V_{TX1} may be transmitted simultaneously. Accordingly, at the output of the CH1 transmit driver 255, the CH1 transmit signal V_{TX1} combines or sums with the CH0 receive signal V_{RX0}. To process the CH0 receive signal V_{RX0} to generate a CH0 receive data signal D_{RX0}, the CH1 transmit signal V_{TX1} should be substantially removed from a first (e.g., positive) input of the CH0 receiver 265. In this regard, the output of the CH1 transmit driver 255 is coupled to a first input of the signal combiner 260.

The inverter 270 includes an input coupled to the input of the CH1 transmit driver 255 to receive the CH1 transmit data signal D_{TX1}. The inverter 270 is configured to invert the CH1 transmit data signal D_{TX1} to generate an inverted CH1 transmit data signal D̅_̅{̅T̅X̅1̅}̅. The CH1 replica transmit driver 275 includes an input coupled to the output of the inverter 270 to receive the inverted CH1 transmit data signal D̅_̅{̅T̅X̅1̅}̅. The CH1 replica transmit driver 275 is configured to power amplify the inverted CH1 transmit data signal D̅_̅{̅T̅X̅1̅}̅ to generate a replica CH1 transmit signal V̅_̅{̅T̅X̅1̅}̅. The replica transmit driver 275 includes an output coupled to a second input of the signal combiner 260.

The CH1 receiver 265 includes a first (e.g., positive) input coupled to an output of the signal combiner 260. Due to the inverter 270 and the replica transmit driver 275, the replica CH1 transmit signal V̅_̅{̅T̅X̅1̅}̅ is substantially equal in amplitude and opposite in phase (e.g., 180 degree out-of-phase) to the CH1 transmit signal V_{TX1}. Thus, the replica CH1 transmit signal V̅_̅{̅T̅X̅1̅}̅ substantially cancels out the CH1 transmit signal V_{TX1} at the output of the signal combiner 260. Accordingly, the signal combiner 260 is configured to substantially output only the CH0 receive signal V_{RX0}. The CH0 receiver 265 includes a second (e.g., negative) input configured to receive a reference voltage V_{REF} (e.g., at a common mode voltage level). Accordingly, the first (e.g., positive) input of the CH0 receiver 265 is configured to receive the CH0 receive signal V_{RX0}. The CH0 receiver 265 is configured to compare the CH0 receive signal V_{RX0} with the reference voltage V_{REF} to generate the CH0 receive signal D_{RX0}.

FIG. 2B illustrates graphs of example transmit signals V_{TX0} and V_{TX1} associated with the simultaneous bidirectional data communication link 200 in accordance with another aspect of the disclosure. The horizontal axis of the graphs represents unit interval (UI) number associated with the transmit signals V_{TX0} and V_{TX1} ranging from zero (0) to above 120. The vertical axis of the graphs, from top to bottom, represents the line voltage in Volt (V) associated with the CH0 transmit signal V_{TX0}, the CH1 transmit signal V_{TX1}, and combined or summed signals V_{TX0}+V_{RX1} or V_{TX1}+V_{RX0} at the output of the CH0 transmit driver 210 or CH1 transmit driver 255, respectively. The range of each of the vertical axis of the graphs is from 0V to 0.4V, the latter of which represents a practical driver voltage for transmit drivers 210, 225, 255, or 275.

In this example, the CH0 transmit signal V_{TX0} may be a non-return-to-zero (NRZ) signal with a top amplitude of 0.2V and a bottom amplitude of 0V. Similarly, the CH1 transmit signal V_{TX1} may be a NRZ signal also with a top amplitude of 0.2V and a bottom amplitude of 0V. The combined or summed signals V_{TX0}+V_{RX1} or V_{TX1}+V_{RX0} at the output of the CH0 transmit driver 210 or CH1 transmit driver 255 exhibit three amplitude levels: 0.4V, 0.2V, and 0V. As previously discussed, the three-amplitude level combined or summed signals is inconsistent with the NRZ data detection signal processing of the receiver 215 and 265. Accordingly, as discussed, the signal combiners 230/260, inverters 220/270, and replica transmit drivers 225/275 are configured to remove the transmit signals V_{TX0} and V_{TX1} from the first (e.g., positive) inputs of the receiver 215 and 265, respectively.

FIG. 2C illustrates a block/signal diagram of a portion of the example simultaneous bidirectional data communication link 200 in accordance with another aspect of the disclosure. As shown, the simultaneous bidirectional data communication link 200 includes the CH0 transmit driver 210 including the output coupled to the first (e.g., left) end of the communication channel 245 and the CH1 transmit driver 255 including the output coupled to the second (e.g., right) end of the communication channel 245. In this example, the CH1 transmit driver 255 is not transmitting as indicated by its input being coupled to ground.

As previously discussed, the replica transmit driver 225 is configured to generate a replica transmit signal V̅_̅{̅T̅X̅0̅}̅ that is substantially equal in terms of amplitude and opposite in terms of phase with the transmit signal V_{TX0} to substantially achieve cancellation at the output of the signal combiner 230. If the replica transmit signal V̅_̅{̅T̅X̅0̅}̅ is not substantially equal in terms of amplitude and opposite in terms of phase with the transmit signal V_{TX0}, the incomplete cancelled signal ends up at the first input (e.g., positive) of the receiver 215 along with the received signal V_{RX1}. This may adversely affect the data detection of the received signal V_{RX1} to generate the received data signal D_{RX1}. As discussed further herein, the replica transmit signal V̅_̅{̅T̅X̅0̅}̅ may not be substantially equal to in amplitude and opposite in phase to the transmit signal V_{TX0} due to signal reflections present at the output of the transmit driver 210.

More specifically, as previously discussed, the output impedance R_{TX} (e.g., 35Ω) of the transmit driver 210 may differ from the characteristic impedance Z₀ (e.g., 50Ω) of the communication channel 245. As a result of the impedance mismatch, a signal artifact (e.g., an overshoot) in the transmit signal V_{TX0} may occur following the rising edge of the transmit signal V_{TX0} due to near-end reflection as shown. Further, there is also an impedance mismatch between the output impedance R_{TX} (e.g., 35Ω) of the transmit driver 255 and the characteristic impedance Z₀ (e.g., 50Ω) of the communication channel 245. This produces a far-end signal reflection at the output of the transmit driver 255, which propagates through the communication channel 245 to produce another signal artifact (e.g., an undershoot) following the near-end signal artifact (e.g., overshoot) in the transmit signal V_{TX0}.

With regard to the falling edge, the near-end signal reflection due to the impedance mismatch between the output impedance R_{TX} of the transmit driver 210 and the characteristic impedance Z₀ produces a signal artifact (e.g., an overshoot in the negative direction) following the falling edge of the transmit signal V_{TX0}, as shown. The far-end signal reflection due to the impedance mismatch between the output impedance R_{TX} of the transmit driver 255 and the characteristic impedance Z₀ of the communication channel 245 produces a signal artifact (e.g., an undershoot in the positive direction) following the near-end signal artifact (e.g., overshoot) in the transmit signal V_{TX0}, as shown.

As the replica transmit driver 225 does not see such impedance mismatch at its output, the replica transmit signal V̅_̅{̅T̅X̅0̅}̅ does not include the signal artifacts (e.g., overshoots and undershoots) present in the transmit signal V_{TX0}. Accordingly, the replica transmit signal V̅_̅{̅T̅X̅0̅}̅ differs from the transmit signal V_{TX0}, which, as discussed, produces incomplete signal cancellation at the first (e.g., positive) input of the receiver 215, which may adversely affect the data detection in the received signal V_{RX1}.

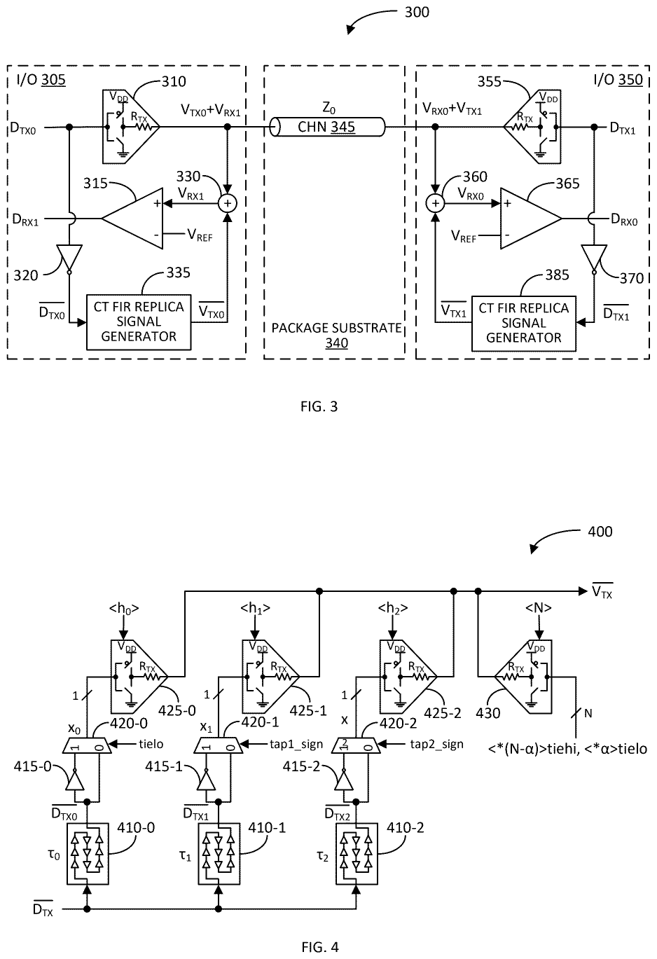

FIG. 3 illustrates a block diagram of an example simultaneous bidirectional data communication link 300 in accordance with another aspect of the disclosure. As discussed further herein, the simultaneous bidirectional data communication link 300 includes a continuous-time (CT) finite impulse response (FIR) replica signal generator configured to generate a replica transmit signal that includes replica near and far reflection signal artifacts (e.g., overshoots and undershoots) such that the replica transmit signal is substantially equal to in amplitude and opposite in phase to the transmit signal for substantial cancellation at an output of a signal combiner so that the receiver processes the receive signal to detect the data therein.

The simultaneous bidirectional data communication link 300 is similar to simultaneous bidirectional data communication link 200, and includes many similar elements as indicated by the same reference numbers with the exception that their most significant digit is a “3” for simultaneous bidirectional data communication link 300 rather than a “2” for simultaneous bidirectional data communication link 200.

The simultaneous bidirectional data communication link 300 primarily differs from simultaneous bidirectional data communication link 200 in that it includes a continuous-time (CT) finite impulse response (FIR) replica signal generator 335 in place of replica transmit driver 225 in the first I/O circuit 305, and a CT FIR replica signal generator 385 in place of replica transmit driver 275 in the second I/O circuit 350.

As discussed with reference to an example detailed implementation of the signal generators 335/385, the CT FIR replica signal generators 335/385 are configured to replicate the near-end and far-end reflection signal artifacts (e.g., overshoots and/or undershoots) in the transmit signals V_{TX0}/V_{TX1} due to the impedance mismatch between the output impedances R_{TX} (e.g., 35Ω) of the transmit drivers 310/355 and the characteristic impedance Z₀ (e.g., 50Ω) of the communication channel 345. This ensures that the replica transmit signals V̅_̅{̅T̅X̅0̅}̅/V̅_̅{̅T̅X̅1̅}̅ are substantially equal to in amplitude, and opposite in phase to the transmit signals V_{TX0}/V_{TX1} for substantial cancellation at the outputs of the signal combiners 330/360. Thereby, allowing the receiver (e.g., VGA and/or CTLE) 315/365 to receive and process substantially only the receive signals V_{RX1}/V_{RX0} for detection of data therein (e.g., for generating receive data signals D_{RX1}/D_{RX0}).

FIG. 4 illustrates a block diagram of an example continuous-time (CT) finite impulse response (FIR) replica signal generator 400 in accordance with another aspect of the disclosure. The CT FIR replica signal generator 400 may be an example implementation of any of the CT FIR replica signal generators 335 and 385 of simultaneous bidirectional data communication link 300. The CT FIR replica signal generator 400 includes a set of delay elements 410-0, 410-1, and 410-2, a set of inverters 415-0, 415-1, and 415-2, a set of multiplexers 420-0, 420-1, and 420, a set of transmit drivers 425-0, 425-1, and 420-2, and a load transmit driver 430 implemented as a programmable load.

The set of delay elements 410-0, 410-1, and 410-2 include inputs coupled together and configured to receive an inverted data transmit signal D̅_̅{̅T̅X̅}̅ (e.g., generated by inverter 320). The set of delay elements 410-0, 410-1, and 410-2 are configured to delay the inverted data transmit signal D̅_̅{̅T̅X̅}̅ by delays τ₀, τ₁, and τ₂ to generate a set of inverted delayed digital transmit signals D̅_̅{̅T̅X̅0̅}̅, D̅_̅{̅T̅X̅1̅}̅, and D̅_̅{̅T̅X̅2̅}̅ at their respective outputs. The outputs of the set of delay elements 410-0, 410-2, and 410-2 are coupled to inputs of the set of inverters 415-0, 415-1, and 415-2 and the zero (0) inputs of the set of multiplexers 420-0, 420-1, and 420-2, respectively. The set of inverters 415-0, 415-1, and 415-2 include outputs coupled to the one (1) inputs of the set of multiplexers 420-0, 420-1, and 420-2, respectively.

The set of multiplexers 420-0, 420-1, and 420-0 include select inputs configured to receive select control signals tielo, tap1_sign, and tap2_sign, respectively. The tielo select signal configures the multiplexer 420-0 to always output the inverted delayed transmit signal D̅_̅{̅T̅X̅0̅}̅ at its zero (0) input as, for simplicity, output signal x₀. Accordingly, the inverter 415-0/multiplexer 420-0 are provided for component matching with the inverter 415-1/multiplexer 420-1 and inverter 415-2/multiplexer 420-2. The multiplexers 420-1 and 420-2 may either output the inverted delayed digital transmit signals D̅_̅{̅T̅X̅1̅}̅, and D̅_̅{̅T̅X̅2̅}̅ at their zero (0) inputs if the select signals tap1_sign and tap2_sign are zero (0), or the (double-inverted) delayed digital transmit signals D_{TX1} and D_{TX2} if the select signals tap1_sign and tap2_sign are one (1) to generate, for simplicity, output signals x₁ and x₂, respectively. For clarity, the select signals tap1_sign and tap2_sign may have different values.

The set of transmit drivers 425-0 to 425-2 include inputs coupled to outputs of the set of multiplexers 420-0, 420-1, and 420-2 to receive the set of signals x₀, x₁, and x₂, respectively. Each of the set of transmit drivers 425-0 to 425-2 includes a set of parallel drivers that may be enabled based on a corresponding input FIR filter coefficient. For example, the set of transmit drivers 425-0 to 425-2 include control inputs to receive a set of FIR filter coefficients h₀, h₁, and h₂, respectively. The set of FIR filter coefficients h₀, h₁, and h₂ may each have a certain bit width, for example, five (<5:0>). Thus, each of the set of FIR filter coefficients h₀, h₁, and h₂ may have a value from zero (00000) to 32 (11111).

As an example, if the value of FIR filter coefficient h₀ is 17 (10001), then transmit driver 425-0 has 17 enabled parallel drivers. If the value of FIR filter coefficient h₁ is 2 (00010), then transmit driver 425-0 has 2 enabled parallel drivers. If the value of FIR filter coefficient h₂ is 1 (00001), then transmit driver 425-2 has 1 enabled parallel driver. If the FIR coefficient is indicated as having a negative value (e.g., h₁=−2), then the corresponding FIR coefficient h is given by its absolute value (e.g., h₁=2), and the corresponding tap_sign is a one (1) so that the corresponding multiplexer (e.g., 420-1) outputs its number one (1) input, which is the (double-inverted) delayed data signal D_{TX1} (e.g., effectuates the negative FIR coefficient h₁=−2).

As discussed, the load transmit driver 430 presents a load impedance to the set of transmit drivers 425-0 and 425-2 based on a value N. Accordingly, the load transmit driver 430 includes a control input configured to receive the value N. Similarly, the load transmit driver 430 includes a set of parallel drivers that may be enabled based on first control input N. The input of load transmit driver 430 is configured to receive a second control signal to configure N-α of the N-enabled parallel drivers to couple their outputs to the upper voltage rail V_{DD} (“tiedhi”) and α of the N-enabled parallel drivers to couple their outputs to the lower voltage rail (e.g., ground) (“tiedlo”). The N value controls the peak-to-peak swing of the replica transmit signal V̅_̅{̅T̅X̅}̅, and α value inversely controls the common mode voltage level of the replica transmit signal V̅_̅{̅T̅X̅}̅.

Further, the delays τ₀, τ₁, and τ₂ control where the amplitudes of the replica transmit signal V̅_̅{̅T̅X̅}̅ based on the FIR filter coefficients h₀, h₁, and h₂ occur. For example, the delay τ₀ may be associated with aligning the edges the amplitude of the replica transmit signal V̅_̅{̅T̅X̅}̅ with the transmit signal V_{TX}, and essentially controls where the replica near reflection signal artifact (e.g., overshoot) occurs in the replica transmit signal V̅_̅{̅T̅X̅}̅. The delay τ₁ may be associated with the amplitude of the replica transmit signal V̅_̅{̅T̅X̅}̅ to where the replica far-end reflection signal artifact (e.g., undershoot) occurs in the replica transmit signal V̅_̅{̅T̅X̅}̅. The delay τ₂ may be associated with the beginning of the steady-state amplitude of the replica transmit signal V̅_̅{̅T̅X̅}̅.

For example, with further reference to FIG. 2C, the delay τ₀ may be associated with the near-end reflection signal artifact (e.g., overshoot) following the rising edge in the transmit signal V_{TX0}. The delay τ₁ may be associated with the far-end reflection signal artifact (e.g., undershoot) following the near-end reflection signal artifact (e.g., overshoot) in the transmit signal V_{TX0}. The delay τ₂ may be associated with the beginning of the steady-state following the undershoot in the transmit signal V_{TX0}. Similarly, the delay τ₀ may be associated with the near-end reflection signal artifact (e.g., overshoot in the negative direction) following the falling edge in the transmit signal V_{TX0}. The delay τ₁ may be associated with the far-end reflection signal artifact (e.g., undershoot in the negative direction) following the near-end reflection signal artifact (e.g., overshoot) in the transmit signal V_{TX0}. The delay τ₂ may be associated with the beginning of the steady-state following the far-end reflection signal artifact (e.g., undershoot) in the transmit signal V_{TX0}.

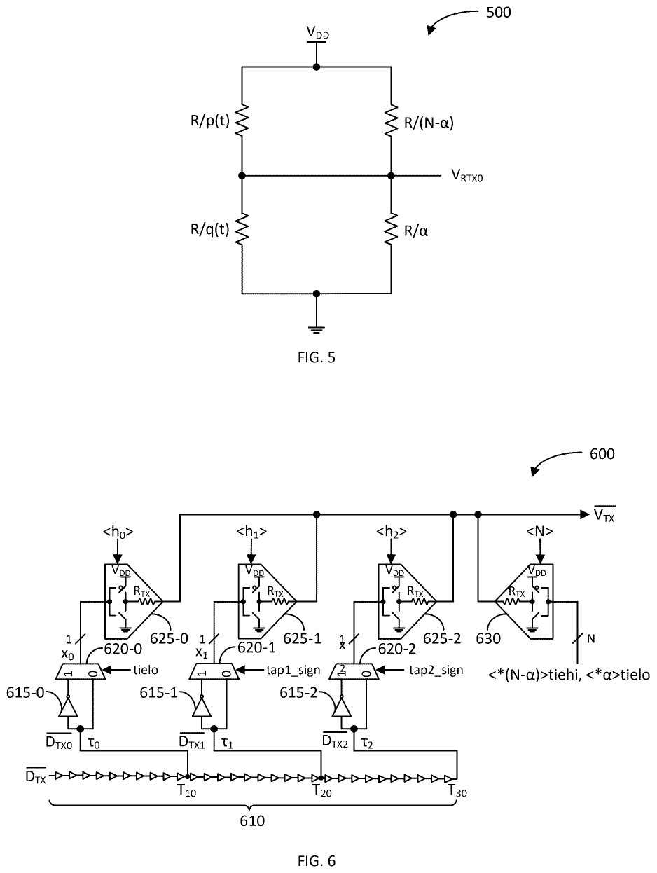

FIG. 5 illustrates a schematic diagram of an example equivalent circuit 500 of the continuous-time (CT) finite impulse response (FIR) replica signal generator 400 in accordance with another aspect of the disclosure. The equivalent circuit 500 includes a first resistor R/p(t) coupled in series with a second resistor R/q(t) between the upper voltage rail V_{DD} and the lower voltage rail (e.g., ground), wherein R is the output resistance of each of the parallel drivers of the transmit drivers 425-0, 425-1, and 425-2. The parameter p (t) is related to the number of the parallel drivers that are “tiedhi” at a given time “t” in the transmit drivers 425-0, 425-1, and 425-2. The parameter q(t) is related to the number of parallel drivers that are “tiedlo” at a given time “t” in the transmit drivers 425-0, 425-1, and 425-2.

The equivalent circuit 500 further includes a third resistor R/(N-α) coupled in series with a fourth resistor R/α between the upper voltage rail V_{DD} and the lower voltage rail (e.g., ground), wherein R is the output resistance of each of the parallel drivers of the load transmit driver 430. N-α is the number of parallel drivers in the load transmit driver 430 that are “tiedhi” and α is the number of parallel drivers in the load transmit driver 430 that are “tiedlo”.

With regard to the instantaneous output voltage of the replica transmit signal V̅_̅{̅T̅X̅}̅, the replica transmit signal V̅_̅{̅T̅X̅}̅ may be given by the following equation:

$$\overline{{V}_{TX}} = {V}_{D D} \cdot \frac{p ( t ) + N - α}{p ( t ) + q ( t ) + N} \qquad Eq . 1$$

$$q ( t ) = \frac{1}{2} \cdot [ {\sum }_{k = 0}^{2} \vert {h}_{k} x ( t - {τ}_{k} ) \vert - {\sum }_{k = 0}^{2} {h}_{k} x ( t - {τ}_{k} ) ] \qquad Eq . 2$$

$$p ( t ) = {\sum }_{k = 0}^{2} \vert {h}_{k} x ( t - {τ}_{k} ) \vert - q ( t ) \qquad Eq . 3$$

With regard to the steady-state of the p and q values, the following equations apply:

$${q}_{OH} = \frac{1}{2} \cdot [ {\sum }_{k = 0}^{2} \vert {h}_{k} \vert - {\sum }_{k = 0}^{2} {h}_{k} ] \qquad Eq . 4$$

$${p}_{OH} = \frac{1}{2} \cdot [ {\sum }_{k = 0}^{2} \vert {h}_{k} \vert - {q}_{OH} ] \qquad Eq . 5$$

$${q}_{OH} = {P}_{OH} \qquad Eq . 6$$

$${q}_{OH} = {P}_{OH} \qquad Eq . 7$$

Where q_{OH} is the logic high steady-state voltage of the replica transmit signal V̅_̅{̅T̅X̅}̅ associated with the q parameter (e.g., the number of parallel drivers tiedlo at steady-state); p_{OH} is the logic high steady-state voltage of the replica transmit signal V̅_̅{̅T̅X̅}̅ associated with the p parameter (e.g., the number of parallel drivers tiedhi at steady-state); q_{OL} is the logic low steady-state voltage of the replica transmit signal V̅_̅{̅T̅X̅}̅ associated with the q parameter (e.g., the number of parallel drivers tiedlo at steady-state); and p_{OL} is the logic low steady-state voltage of the replica transmit signal V̅_̅{̅T̅X̅}̅ associated with the p parameter (e.g., the number of parallel drivers tiedhi at steady-state).

As an example, the difference between the logic high voltage V_{OH} and logic low voltage V_{OL} of the replica transmit signal V_{TX} may be set to V_{DD}/2 based on the following equations:

$$\frac{{p}_{OH} - {q}_{OH}}{{p}_{OH} - {q}_{OH} + N} = \frac{1}{2} \qquad Eq . 8$$

$$N = {P}_{OH} - 3 {q}_{OH} \qquad Eq . 9$$

FIG. 6 illustrates a block diagram of another example continuous-time (CT) finite impulse response (FIR) replica signal generator 600 in accordance with another aspect of the disclosure. The CT FIR replica signal generator 600 is a variation of the CT FIR replica signal generator 400 previously discussed, and includes many of the same/similar elements as indicated by the same reference numbers with the exception that their most significant digit is a “6” for CT FIR replica signal generator 600 instead of a “4” for CT FIR replica signal generator 400.

The CT FIR replica signal generator 600 differs from CT FIR replica signal generator 400 in that it includes a delay line 610 that includes a set of cascaded delay elements extending from an input configured to receive the inverted digital transmit signal D̅_̅{̅T̅X̅}̅ to an output, which may be coupled to the inputs of the inverter 615-2 and the zero (0) input of the multiplexer 620-2.

As an example, the output of the 10^{th} cascaded inverter of delay line 610, which produces the delay τ₀ of the transmit data signal D_{TX0} and may be referred to as the tap T₁₀, may be coupled to the inputs of the inverter 615-0 and the zero (0) input of the multiplexer 620-0. The output of the 20^{th} cascaded inverter of delay line 610, which produces the delay τ₁ of the united transmit data signal D̅_̅{̅T̅X̅}̅ and may be referred to as the tap T₂₀, may be coupled to the input of the inverter 615-1 and the zero (0) input of the multiplexer 620-1. The output of the 30^{th} cascaded inverter of delay line 610, which produces the delay 12 of the inverted transmit data signal D̅_̅{̅T̅X̅}̅ and may be referred to as the tap T₃₀, may be coupled to the input of the inverter 615-2 and the zero (0) input of the multiplexer 620-2.

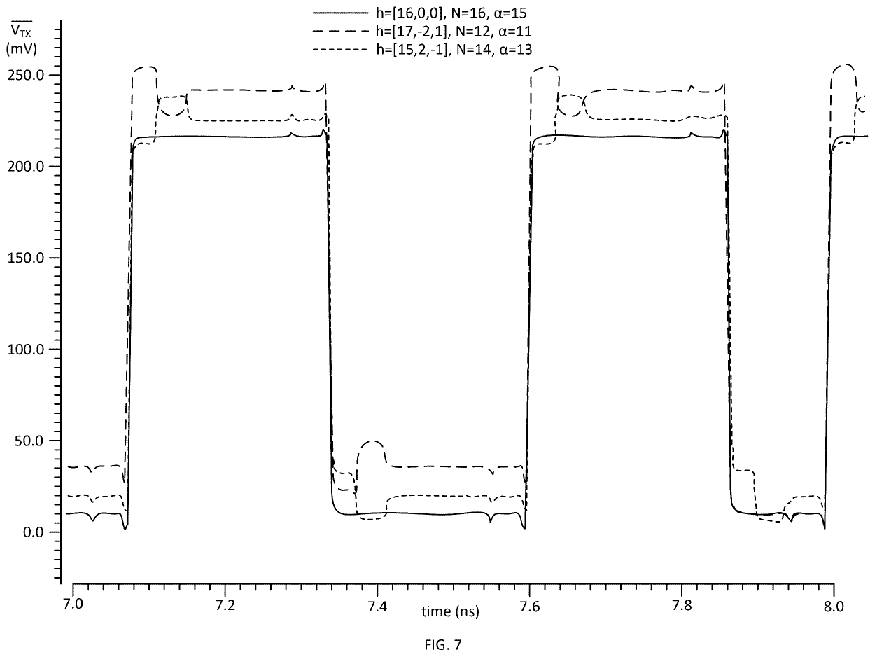

FIG. 7 illustrates a graph of example replica transmit signals V̅_̅{̅T̅X̅}̅ generated by the CT FIR replica signal generator 400 or 600 in accordance with another aspect of the disclosure. The horizontal axis of the graph represents time in nanoseconds (ns) extending from 7.0 ns to 8.0 ns. The vertical axis represents the replica transmit signals V_{TX} in milli Volt (mV) extending from below 0.0 mV to above 250 mV. The graph depicts three (3) example transmit signals V̅_̅{̅T̅X̅}̅ as indicated by a solid line, a long-dash line, and a short-dash line.

More specifically, the solid line represents replica transmit signal V̅_̅{̅T̅X̅}̅ that does not include any signal reflection artifacts (e.g., no overshoots or undershoots). In this regard, the FIR coefficients h₀, h₁, and h₂ associated with the transmit drivers 425-0/625-0 to 425-2/625-2 are respectively [16, 0, 0], the N parameter is 16, and the a parameter is 15. The h₀ FIR coefficient is 16 indicating the amplitude of the replica transmit signal V̅_̅{̅T̅X̅}̅ after each transition. The h₁ and h₂ FIR coefficients are zero (0) indicating that there is no change in the amplitude of the replica transmit signal V_{TX} after each transition. Further, the h₀ FIR coefficient is the same as the N parameter indicating that the amplitude of the replica transmit signal V̅_̅{̅T̅X̅}̅ after each transition is the same as the peak-to-peak amplitude of the replica transmit signal V_{TX}. And the common mode voltage level of the replica transmit signal V̅_̅{̅T̅X̅}̅ may be set by an α parameter of 15. As shown, the replica transmit signals V̅_̅{̅T̅X̅}̅ is substantially square wave as the h₁ and h₂ FIR coefficients being zero (0) indicates no change in amplitude with regard to the amplitude after each transition as indicated by the h₀=16 FIR coefficient.

The long-dash line represents replica transmit signals V̅_̅{̅T̅X̅}̅ that includes a near-end reflection signal artifact (e.g., overshoot) and a far-end reflection signal artifact (e.g., undershoot). In this regard, the FIR coefficients h₀, h₁, and h₂ associated with the transmit drivers 425-0/625-0 are respectively [17, −2, 1], N parameter is 12, and the α is 11. The h₀ FIR coefficient being 17, above the peak-to-peak level 16 indicated by the sum of all three taps, replicates the near-end reflection overshoot following each transition in the replica transmit signals V̅_̅{̅T̅X̅}̅. The h₁ FIR coefficient being-2 replicates the far-end reflection undershoot following the near-end reflection overshoot in the replica transmit signals V̅_̅{̅T̅X̅}̅. The h₂ FIR coefficient being one (1) replicates the rise to steady-state following the far-end reflection undershoot in the replica transmit signal V̅_̅{̅T̅X̅}̅. The common mode voltage level of the replica transmit signal V̅_̅{̅T̅X̅}̅ may be set by an α parameter of 11.

The short-dashed line represents replica transmit signals V̅_̅{̅T̅X̅}̅ that includes a small near-end reflection overshoot and a large far-end reflection overshoot. In this regard, the FIR coefficients h₀, h₁, and h₂ associated with the transmit drivers 425-0/625-0 are respectively [15, 2, −1], N parameter is 14, and the a is 13. The h₀ FIR coefficient being 15, above the peak-to-peak level 16 indicated by the sum of all three taps, replicates the small near-end reflection overshoot following each transition in the replica transmit signal V̅_̅{̅T̅X̅}̅. The h₁ FIR coefficient being 2 replicates the large far-end reflection overshoot following the near-end reflection overshoot in the replica transmit signal V̅_̅{̅T̅X̅}̅. The h₂ FIR coefficient being −1 replicates the decrease to steady-state following the far reflection overshoot in the replica transmit signal V̅_̅{̅T̅X̅}̅. The common mode voltage level of the replica transmit signal V̅_̅{̅T̅X̅}̅ may be set by an α parameter of 13.

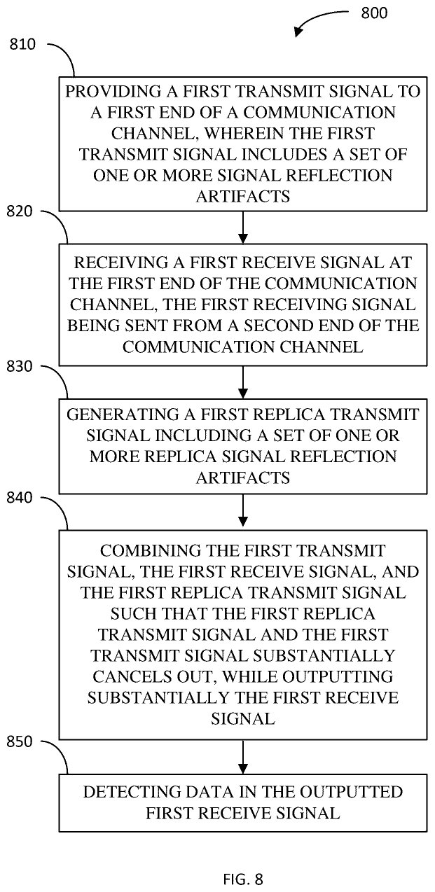

FIG. 8 illustrates a flow diagram of an example method 800 of receiving a data signal in accordance with another aspect of the disclosure. The method 800 includes providing a first transmit signal to a first end of a communication channel, wherein the first transmit signal includes a set of one or more signal reflection artifacts (block 810). Examples of means of providing first transmit signal to a first end of a communication channel includes any of the transmit drivers 310/355 described herein. The method 800 further includes receiving a first receive signal at the first end of the communication channel, the first receiving signal being sent from a second end of the communication channel (block 820). Examples of means includes receiving a first receive signal at the first end of the communication channel includes any of the transmit drivers 310/355 coupled to the communication channel 345 described herein.

The method 800 further generating a first replica transmit signal including a set of one or more replica signal reflection artifacts (block 830). Examples of means for generating a first replica transmit signal including a set of one or more replica signal reflection artifacts include any of the CT FIR replica signal generators 335, 385, 400, and 600 described herein. Additionally, the method 800 includes combining the first transmit signal, the first receive signal, and the first replica transmit signal such that the first replica transmit signal and the first transmit signal substantially cancels out, while outputting substantially the first receive signal (block 840). Examples of means for combining the first transmit signal, the first receive signal, and the first replica transmit signal such that the first replica transmit signal and the first transmit signal substantially cancels out, while outputting substantially the first receive signal include any of the signal combiners 330 and 360 described herein. Further, the method includes detecting data in the outputted first receive signal (block 850). Examples of means for detecting data in the outputted first receive signal includes any of the receiver 315 and 365 described herein.

The following provides an overview of aspects of the present disclosure:

Aspect 1: An apparatus, comprising: a first input/output (I/O) circuit comprising: a first transmit driver; a first continuous-time (CT) finite impulse response (FIR) replica signal generator including an input directly or indirectly coupled to an input of the first transmit driver; a first signal combiner including a first input coupled to an output of the first transmit driver, and a second input coupled to an output of the first CT FIR replica signal generator; and a first receiver including a first input coupled to an output of the first signal combiner.

Aspect 2: The apparatus of aspect 1, wherein the first I/O circuit further comprises a first inverter including an input coupled to the input of the first transmit driver and an output coupled to the input of the first CT FIR replica signal generator.

Aspect 3: The apparatus of aspect 1 or 2, wherein the first CT FIR replica signal generator comprises: a set of delay elements including inputs coupled together and directly or indirectly coupled to the input of the first transmit driver; a set of inverters including inputs coupled to outputs of the set of delay elements, respectively; a set of multiplexers including first inputs coupled to the outputs of the set of delay elements, second inputs coupled to outputs of the set of inverters, select inputs configured to receive a set of control signals, and a set of outputs, respectively; and a set of transmit drivers including inputs coupled to outputs of the set of multiplexers, respectively.

Aspect 4: The apparatus of aspect 3, wherein the set of transmit drivers include control inputs configured to receive a set of FIR coefficients, respectively.

Aspect 5: The apparatus of aspect 4, wherein the set of transmit drivers include sets of parallel drivers, respectively, wherein the set of FIR coefficients are configured to enable zero (0) or more of the sets of parallel drivers of the set of transmit drivers, respectively.

Aspect 6: The apparatus of any one of aspects 3-4, further comprising a load transmit driver including an output coupled to the outputs of the set of transmit drivers.

Aspect 7: The apparatus of aspect 6, wherein the load transmit driver is configured to receive one or more control signals to present a load to the set of transmit drivers.

Aspect 8: The apparatus of aspect 7, wherein the load transmit driver includes a set of parallel transmit drivers, wherein the one or more control signals sets a first subset of the set of parallel transmit drivers to couple a first set of resistors between the outputs of the set of transmit drivers and an upper voltage rail, wherein the one or more control signals also sets a second subset of the set of parallel transmit drivers to couple a second set of resistors between the outputs of the set of transmit drivers and a lower voltage rail.

Aspect 9: The apparatus of any one of aspects 1-8, wherein the first CT FIR replica signal generator comprises: a delay line including an input directly or indirectly coupled to the input of the first transmit driver; a set of inverters including inputs coupled to a set of taps of the delay line, respectively; a set of multiplexers including first inputs coupled to the set of taps of the delay line, second inputs coupled to outputs of the set of inverters, and select inputs configured to receive a set of control signals, respectively; and a set of transmit drivers including inputs coupled to outputs of the set of multiplexers, respectively.

Aspect 10: The apparatus of any one of aspects 1-9, further comprising a second I/O circuit coupled to the first I/O circuit via a communication channel, wherein the output of the first transmit driver is coupled to a first end of the communication channel.

Aspect 11: The apparatus of aspect 10, wherein the second I/O circuit comprises: a second transmit driver including an output coupled to a second end of the communication channel; a second continuous-time (CT) finite impulse response (FIR) replica signal generator including an input directly or indirectly coupled to an input of the second transmit driver; a second signal combiner including a first input coupled to the output of the second transmit driver, and a second input coupled to an output of the second CT FIR replica signal generator; and a second receiver including a first input coupled to an output of the second signal combiner.

Aspect 12: The apparatus of aspect 11, wherein the first I/O circuit further comprises a second inverter including an input coupled to the input of the second transmit driver and an output coupled to the input of the second CT FIR replica signal generator.

Aspect 13: A method, comprising: providing a first transmit signal to a first end of a communication channel, wherein the first transmit signal includes a set of one or more signal reflection artifacts; receiving a first receive signal at the first end of the communication channel, the first receiving signal being sent from a second end of the communication channel; generating a first replica transmit signal including a set of one or more replica signal reflection artifacts; combining the first transmit signal, the first receive signal, and the first replica transmit signal such that the first replica transmit signal and the first transmit signal substantially cancels out, while outputting substantially the first receive signal; and detecting data in the outputted first receive signal.

Aspect 14: The method of aspect 13, wherein the set of one or more signal reflection artifacts is due to a signal reflection occurring at the first end of the communication channel.

Aspect 15: The method of aspect 13 or 14, wherein the set of one or more signal reflection artifacts is due to a signal reflection occurring at the second end of the communication channel.

Aspect 16: The method of one of aspects 13-15, wherein: the set of one or more signal reflection artifacts includes an overshoot immediately following a transition in the first transmit signal; and the set of one or more replica signal reflection artifacts includes a replica overshoot substantially time aligned with the overshoot of the first transmit signal.

Aspect 17: The method of aspect 16, wherein the replica overshoot is substantially equal in amplitude and opposite in phase with respect to the overshoot in the first transmit to achieve substantial cancellation when combining the first transmit signal with the first replica transmit signal.

Aspect 18: The method of aspect 16 or 17, wherein the overshoot is due to a signal reflection at the first end of the communication channel.

Aspect 19: The method of any one of aspects 16-18, wherein: the set of one or more signal reflection artifacts includes an undershoot immediately following the overshoot in the first transmit signal, wherein the undershoot is due to a signal reflection at the second end of the communication channel; and the set of one or more replica signal reflection artifacts includes a replica undershoot substantially time aligned with the undershoot of the first transmit signal.

Aspect 20: The method of aspect 19, wherein the replica undershoot is substantially equal in amplitude and opposite in phase with respect to the undershoot in the first transmit to achieve substantial cancellation when combining the first transmit signal with the first replica transmit signal.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed:

1. An apparatus, comprising:
a first input/output (I/O) circuit comprising:
a first transmit driver;
a first continuous-time (CT) finite impulse response (FIR) replica signal generator including an input directly or indirectly coupled to an input of the first transmit driver;
a first signal combiner including a first input coupled to an output of the first transmit driver, and a second input coupled to an output of the first CT FIR replica signal generator; and
a first receiver including a first input coupled to an output of the first signal combiner.

2. The apparatus of claim 1, wherein the first I/O circuit further comprises a first inverter including an input coupled to the input of the first transmit driver and an output coupled to the input of the first CT FIR replica signal generator.

3. The apparatus of claim 1, wherein the first CT FIR replica signal generator comprises:
a set of delay elements including inputs coupled together and directly or indirectly coupled to the input of the first transmit driver;
a set of inverters including inputs coupled to outputs of the set of delay elements, respectively;
a set of multiplexers including first inputs coupled to the outputs of the set of delay elements, second inputs coupled to outputs of the set of inverters, select inputs configured to receive a set of control signals, and a set of outputs, respectively; and
a set of transmit drivers including inputs coupled to outputs of the set of multiplexers, respectively.

4. The apparatus of claim 3, wherein the set of transmit drivers include control inputs configured to receive a set of FIR coefficients, respectively.

5. The apparatus of claim 4, wherein the set of transmit drivers include sets of parallel drivers, respectively, wherein the set of FIR coefficients are configured to enable zero (0) or more of the sets of parallel drivers of the set of transmit drivers, respectively.

6. The apparatus of claim 3, further comprising a load transmit driver including an output coupled to the outputs of the set of transmit drivers.

7. The apparatus of claim 6, wherein the load transmit driver is configured to receive one or more control signals to present a load to the set of transmit drivers.

8. The apparatus of claim 7, wherein the load transmit driver includes a set of parallel transmit drivers, wherein the one or more control signals sets a first subset of the set of parallel transmit drivers to couple a first set of resistors between the outputs of the set of transmit drivers and an upper voltage rail, wherein the one or more control signals also sets a second subset of the set of parallel transmit drivers to couple a second set of resistors between the outputs of the set of transmit drivers and a lower voltage rail.

9. The apparatus of claim 1, wherein the first CT FIR replica signal generator comprises:
a delay line including an input directly or indirectly coupled to the input of the first transmit driver;
a set of inverters including inputs coupled to a set of taps of the delay line, respectively;
a set of multiplexers including first inputs coupled to the set of taps of the delay line, second inputs coupled to outputs of the set of inverters, and select inputs configured to receive a set of control signals, respectively; and
a set of transmit drivers including inputs coupled to outputs of the set of multiplexers, respectively.

10. The apparatus of claim 1, further comprising a second I/O circuit coupled to the first I/O circuit via a communication channel, wherein the output of the first transmit driver is coupled to a first end of the communication channel.

11. The apparatus of claim 10, wherein the second I/O circuit comprises:
a second transmit driver including an output coupled to a second end of the communication channel;
a second continuous-time (CT) finite impulse response (FIR) replica signal generator including an input directly or indirectly coupled to an input of the second transmit driver;
a second signal combiner including a first input coupled to the output of the second transmit driver, and a second input coupled to an output of the second CT FIR replica signal generator; and
a second receiver including a first input coupled to an output of the second signal combiner.

12. The apparatus of claim 11, wherein the first I/O circuit further comprises a second inverter including an input coupled to the input of the second transmit driver and an output coupled to the input of the second CT FIR replica signal generator.

13. A method, comprising:
providing a first transmit signal to a first end of a communication channel, wherein the first transmit signal includes a set of one or more signal reflection artifacts;
receiving a first receive signal at the first end of the communication channel, the first receiving signal being sent from a second end of the communication channel;
generating a first replica transmit signal including a set of one or more replica signal reflection artifacts;
combining the first transmit signal, the first receive signal, and the first replica transmit signal such that the first replica transmit signal and the first transmit signal substantially cancels out, while outputting substantially the first receive signal; and
detecting data in the outputted first receive signal.

14. The method of claim 13, wherein the set of one or more signal reflection artifacts is due to a signal reflection occurring at the first end of the communication channel.

15. The method of claim 13, wherein the set of one or more signal reflection artifacts is due to a signal reflection occurring at the second end of the communication channel.

16. The method of claim 13, wherein:
the set of one or more signal reflection artifacts includes an overshoot immediately following a transition in the first transmit signal; and
the set of one or more replica signal reflection artifacts includes a replica overshoot substantially time aligned with the overshoot of the first transmit signal.

17. The method of claim 16, wherein the replica overshoot is substantially equal in amplitude and opposite in phase with respect to the overshoot in the first transmit to achieve substantial cancellation when combining the first transmit signal with the first replica transmit signal.

18. The method of claim 16, wherein the overshoot is due to a signal reflection at the first end of the communication channel.

19. The method of claim 16, wherein:
the set of one or more signal reflection artifacts includes an undershoot immediately following the overshoot in the first transmit signal, wherein the undershoot is due to a signal reflection at the second end of the communication channel; and
the set of one or more replica signal reflection artifacts includes a replica undershoot substantially time aligned with the undershoot of the first transmit signal.

20. The method of claim 19, wherein the replica undershoot is substantially equal in amplitude and opposite in phase with respect to the undershoot in the first transmit to achieve substantial cancellation when combining the first transmit signal with the first replica transmit signal.
